(19) United States
(12) Patent Application Publication
(10) Pub. No.: US 2007/0241675 A1
(43) Pub. Date: Oct. 18, 2007

(54) Organic electroluminescence device with charge separation layer

(76) Inventors: Mu-Gyeom Kim, Hwaseong-si (KR); O-Hyun Kwon, Seoul (KR); Sang-Hoon Park, Seongnam-si (KR)

Correspondence Address: Robert E. Bushnell, Suite 300, 1522 K Street, N.W., Washington, DC, 20005, US

(21) Appl. No.: 11/723,168

(22) Filed: Mar. 16, 2007

(30) Foreign Application Priority Data
Apr. 13, 2006 (KR) 10-2006-0033539

(51) Int. Cl. H01L 51/54; H01L 51/52

(52) U.S. Cl. 313/506; 428/212; 428/690; 428/917; 313/504; 257/40; 257/E51.049; 257/E51.051

(57) ABSTRACT

Provided is an organic electroluminescence device with an improved structure configured to enhance luminescent efficiency. An organic electroluminescence device includes a charge separation layer interposed between a first organic luminescent layer and a second organic luminescent layer. The charge separation layer includes one of a first charge transport material having greater hole mobility than materials for forming the first and second luminescent layers when electron mobility of the materials for forming the first and second luminescent layers is greater than their hole mobility, and a second charge transport material having greater electron mobility than materials for forming the first and second luminescent layers when hole mobility of the materials for forming the first and second luminescent layers is greater than their electron mobility.

### CROSS-REFERENCE TO RELATED PATENT APPLICATION AND CLAIM OF PRIORITY

This application claims the benefit of Korean Patent Application No. 10-2006-0033539, filed on Apr. 13, 2006, in the Korean Intellectual Property Office, the disclosure of which is incorporated herein in its entirety by reference.

### BACKGROUND OF THE INVENTION

1. Field of the Invention

The present invention relates to an electroluminescence device, and more particularly, to an organic electroluminescence device with an improved structure configured to enhance luminescent efficiency.

2. Description of the Related Art

Organic light emitting diodes (OLEDS) are self-luminescent devices that emit light when electrons and holes are recombined in a fluorescent or phosphor organic layer when current flows to the fluorescent or phosphor organic layer. OLEDs can be manufactured to be lightweight using less number of components through a simple manufacturing process, and can provide high-quality images and wide-view angles. Also, OLED can realize moving images in real time and high chromatic purity and, have electric characteristics suitable for portable electronic devices due to low power consumption and low operation voltage.

OLED can be classified into a small molecular OLED (SMOLED) and a polymer LED (PLED) according to molecular weights of a material for a luminescent layer.

An organic layer of SMOLED often includes a multi-layer structure configured with a hole injection layer, a hole transport layer, an electron transport layer and/or an electron injection layer, and so forth, to make holes and electrons move effectively. A vacuum thermal deposition method or a vapor deposition method is generally employed to form the aforementioned layers. However, the materials used for forming the above mentioned layers have low usage efficiency, and thus, manufacturing costs increase. A technology in development concerning deposition apparatuses for implanting large and wide screens is still not satisfactory.

On the contrary, as compared with SMOLED, an organic layer of PLED disposed between a first electrode and a second electrode has higher mechanical strength and thermal stability, low operation voltage and, can represent various fluorescent colors due to various molecular structures of fluorescent polymers. A solution, obtained by dissolving fluorescent polymers in an appropriate organic solvent, is coated using a coating method such as spin casting, ink jet printing, or spray printing to form the organic layer of such a PLED. Many researchers have actively studied PLED and a manufacturing method thereof.

In a typical organic electroluminescence device structure, an organic luminescent layer is often formed of a material having one property selected from a material with large electron mobility and a material with large hole mobility. Thus, the electron-hole recombination usually takes place locally in a region adjacent to an anode or a cathode. As a result, the typical organic electroluminescence device may have low luminescent efficiency. For instance, if the organic luminescent layer is formed of a material having large electron mobility, the electron-hole recombination takes place locally in a region adjacent to the anode. This regional electron-hole recombination may lower the luminescent efficiency of the organic electroluminescence device. Therefore, organic electroluminescence devices need to have an improved structure that can enhance the luminescent efficiency.

### SUMMARY OF THE INVENTION

The present invention provides an organic electroluminescence device with an improved structure configured to enhance luminescent efficiency.

According to an aspect of the present invention, there is provided an organic electroluminescence device, including an anode, an organic luminescent layer, and a cathode, formed in sequential order, wherein the organic luminescent layer includes a first organic luminescent layer, a second organic luminescent layer, and a charge separation layer, wherein the charge separation layer is interposed between the first organic luminescent layer and the second organic luminescent layer and includes one of a first charge transport material having greater hole mobility than materials for forming the first and second luminescent layers and a second charge transport material having greater electron mobility than materials for forming the first and second luminescent layers.

According to the embodiments of the present invention, interposing the charge separation layer between the multiple layers of the organic luminescent layer (i.e., the first and second organic luminescent layers) allows formation of at least two layers of electron-hole recombination zones separated from each other within the organic luminescent layer. This electron-hole recombination zone structure can improve luminescent efficiency of the organic electroluminescence device.

According to an aspect of the present invention, there is provided an organic electroluminescence device, comprising: an anode; a cathode; and an organic luminescent layer formed between the anode and the cathode, the organic luminescent layer comprising a first organic luminescent layer formed of a first organic luminescent material, a second organic luminescent layer formed of a second organic luminescent material, the first organic luminescent material and the second organic luminescent material having an electron mobility greater than a hole mobility or a hole mobility greater than an electron mobility, and a charge separation layer interposed between the first organic luminescent layer and the second organic luminescent layer, the charge separation layer formed of one of (1) a first charge transport material having greater hole mobility than the first organic luminescent material and the second organic luminescent material when electron mobility of the first organic luminescent material and the second organic luminescent material is greater than hole mobility of the first organic luminescent material and the second organic luminescent material and (2) a second charge transport material having greater electron mobility than the first organic luminescent material and the second organic luminescent material when electron mobility of the first organic luminescent material and the second organic luminescent material is greater than hole mobility of the first organic luminescent material and the second organic luminescent material.

According to an aspect of the present invention, there is provided an organic electroluminescence device, comprising: an anode;

a cathode; and

an organic luminescent layer formed between the anode and the cathode, the organic luminescent layer comprising: a first electron-hole recombination zone; a second electron-hole recombination zone, the first organic electron-hole recombination zone and the second electron-hole recombination zone having one property of electron mobility greater than hole mobility and hole mobility greater than an electron mobility, and a charge separation layer interposed between the first electron-hole recombination zone and the second electron-hole recombination zone, the charge separation layer formed of one of a first charge transport material and a second charge transport material, the first charge transport material comprising one selected from the group consisting of poly(9,9-dioctylfluorene-co-N-(4-butylphenyl)diphenylamine), poly(9,9′-dioctylfluorene-co-bis-N,N′-(4-butylphenyl )-bis-N,N′-phenylbenzidine, and poly(9,9-dioctylfluorene-co-bis-N,N′-(4-butylphenyl)-bis-N,N′-phenyl-1,4-phenylenedi amine, the second charge transport material comprising one selected from the group consisting of PBD (1,3,4-oxadiazole derivatives), Alq3 (tris(8-quinolinolato)aluminum complex) and TPBi (N,arylbenzimidazoles).

### BRIEF DESCRIPTION OF THE DRAWINGS

A more complete appreciation of the present invention, and many of the above and other features and advantages of the present invention, will be readily apparent as the same becomes better understood by reference to the following detailed description when considered in conjunction with the accompanying drawings in which like reference symbols indicate the same or similar components, wherein:

FIG. 1 illustrates a simplified cross-sectional view for showing a basic principle of an organic electroluminescence device;

FIG. 2 illustrates a simplified cross-sectional view of an organic electroluminescence device according to an embodiment of the present invention;

FIG. 3 is a graph illustrating an optical wavelength characteristic of an organic electroluminescence device fabricated according to a first experimental embodiment of the present invention;

FIG. 4 is a graph illustrating luminance characteristics of the organic electroluminescence device fabricated according to Example 1 and Comparative Example 1; and

FIG. 5 is a graph illustrating current efficiency of the organic electroluminescence device fabricated according to Example 1 and Comparative Example 1.

### DETAILED DESCRIPTION OF THE INVENTION

The present invention will now be described more fully with reference to the accompanying drawings, in which exemplary embodiments of the invention are shown. In the drawings, the thicknesses of layers and regions are exaggerated for clarity.

FIG. 1 illustrates a simplified cross-sectional view for showing a basic principle of an organic electroluminescence device.

The organic electroluminescence device includes an anode 12, a cathode 18, and an organic luminescent layer interposed between the anode 12 and the cathode 18. When a certain level of voltage is applied between the anode 12 and the cathode 18, electrons and holes are supplied from the anode 12 and the cathode 18 to the organic luminescent layer 14 and recombined together to emit light. The organic luminescent layer 14 provides an electron-hole recombination zone 14a.

However, in a typical organic electroluminescence device structure, the organic luminescent layer 14 is often formed of a material having one property selected from a material with large electron mobility and a material with large hole mobility. Thus, the electron-hole recombination usually takes place locally in a region adjacent to the anode 12 or cathode 18. As a result, the typical organic electroluminescence device may have low luminescent efficiency. For instance, if the organic luminescent layer 14 is formed of a material having large electron mobility, the electron-hole recombination takes place locally in a region adjacent to the anode 12. This regional electron-hole recombination may lower the luminescent efficiency of the organic electroluminescence device.

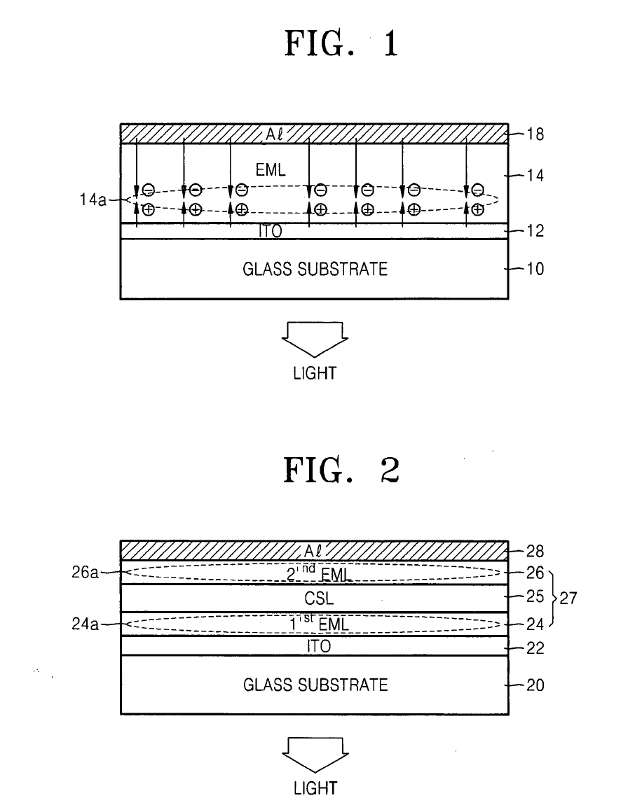

FIG. 2 illustrates a simplified cross-sectional view of an organic electroluminescence device according to an embodiment of the present invention.

Referring to FIG. 2, the organic electroluminescence device includes an anode 22, an organic luminescent layer 27, and a cathode 28 stacked on a transparent substrate 20 in sequential order. The organic luminescent layer 27 includes a first organic luminescent layer 24, a second organic luminescent layer 26, and a charge separation layer 25 interposed therebetween.

The anode 22 may be formed of a transparent conductive material, e.g., indium tin oxide (ITO). The cathode 28 may be formed of a low work function metal selected from the group consisting of aluminum, magnesium, indium, and calcium, or an alloy thereof. Since the materials for the anode 22 and the cathode 28, and a fabrication method thereof are already well known in the art, a detailed description thereof will be omitted.

The charge separation layer 25 may be formed of a first charge transport material or a second charge transport material. The first charge transport material has greater hole mobility than the materials for forming the first and second organic luminescent layers 24 and 26. The second charge transport material has greater electron mobility than the materials for forming the first and second organic luminescent layers 24 and 26. In more detail, the hole mobility of the first charge transport material may range from approximately 1.0×10⁻⁵ cm²/Vs to 1.0×10⁻³ cm²/Vs. For instance, the first charge material may be one selected from the group consisting of TFB (poly(9,9-dioctylfluorene-co-N-(4-butylphenyl)diphenylamine)), BFE (poly(9,9′-dioctylfluorene-co-bis-N,N′-(4-butylphenyl)-bis-N,N′-phenylbenzidine), and PFB (poly(9,9-dioctylfluorene-co-bis-N,N′-(4-butylphenyl)-bis-N,N′-phenyl-1,4-phenylenedi amine)).

The electron mobility of the second charge transport material may range from approximately 1.0×10⁻⁵ cm²/Vs to 1.0×10⁻³ cm²/Vs. For instance, the second charge transport material may be one selected from the group consisting of PBD (1,3,4-oxadiazole derivatives), Alq3 (tris(8-quinolinolato)aluminum complex), and TPBi (N,arylbenzimidazoles).

According to an embodiment of the present invention, interposing the charge separation layer 25 between the multiple layers of the organic luminescent layer 27 (e.g., between the first organic luminescent layer 24 and the second organic luminescent layer 26) can form at least two layers of electron-hole recombination zones that can be distinguished from each other within the organic luminescent layer 27. Such multiple layers of the electron-hole recombination zones can improve luminescent efficiency to a greater extent as compared with the conventional electroluminescence device.

Hereinafter, with reference to FIG. 2, characteristics of the embodied organic electroluminescence device will be described in the following embodiments of the present invention.

### Embodiment 1

The first and second organic luminescent layers 24 and 26 are formed of a first organic luminescent material having greater electron mobility than hole mobility. Polyfluorene (hereinafter referred to as “PF”) based polymers, derivatives of PF based polymers, polyspirofluorene (hereinafter “PSF”) based polymers, and derivatives of PSF based polymers are examples of the first organic luminescent material. The charge separation layer 25 is formed of the first charge transport material as described above. That is, the first charge transport material has greater hole mobility than the materials for forming the first and second organic luminescent layers 24 and 26. Particularly, the first charge transport material has hole mobility ranging from approximately 1.0×10⁻⁵ cm²/Vs to 1.0×10⁻³ cm²/Vs.

In the organic electroluminescence device according to the first embodiment, when a certain level of voltage is applied between the anode 22 and the cathode 28, electrons are supplied from the cathode 28 to the organic luminescent layer 27, and holes are supplied from the anode 22 to the organic luminescent layer 27. Since the first organic luminescent material has large electron mobility but small hole mobility, electrons can be supplied easily to the first and second organic luminescent layers 24 and 26. However, holes are less likely to be supplied to the second organic luminescent layer 26 for the following reason. Among the holes moved to the first organic luminescent layer 24, those redundant holes, i.e., the holes that are not recombined with the electrons, can be transported to the second organic luminescent layer 26. However, the redundant holes have low mobility within the first organic luminescent layer 24, thereby taking a lot of time to reach the second organic luminescent layer 26. For this reason, when the first and second organic luminescent layers 24 and 26 are stacked consecutively, it is difficult to obtain a charge balance between the electrons and the holes within the second organic luminescent layer 26. This difficult charge balance is also applied to the case where the first and second organic luminescent layers 24 and 26 are formed in a bulk type single layer.

Hence, the charge separation layer 25 is interposed between the first organic luminescent layer 24 and the second organic luminescent layer 26, so that the mobility of the redundant holes can be improved within the organic luminescent layer 27. In more detail, the charge separation layer 25 is formed of a material having greater hole mobility than the first organic luminescent material for forming the first and second organic luminescent layers 24 and 26 as a counterpart to the first organic luminescent material. As a result, transport efficiency of the redundant holes can be better when the charge separation layer 25 is interposed between the first organic luminescent layer 24 and the second organic luminescent layer 26 than when the first and second organic luminescent layers 24 and 26 are stacked consecutively. Also, electron and hole concentrations for the recombination within the second organic luminescent layer 26 can be balanced. Thus, a stable light emission phenomenon caused by the electron-hole recombination can take place.

In particular, each of the first and second organic luminescent layers 24 and 26 can provide electron-hole recombination zones 24a and 26a. Thus, interposing the charge separation layer 25 between the multiple layers of the organic luminescent layer 27 can provide at least two layers of the electron-hole recombination zones separated within the organic luminescent layer 27. Such a multiple-layer structure of the electron-hole recombination zones 24a and 26a can improve luminescent efficiency of the organic electroluminescence device.

### Embodiment 2

The first and second organic luminescent layers 24 and 26 are formed of a second organic luminescent material having greater hole mobility than electron mobility. A fluorescent material such as triphenyl amine is one example of the second organic luminescent material. The charge separation layer 25 is formed of the second charge transport material as described above. That is, the second charge transport material has greater electron mobility than the second organic luminescent material. Particularly, the electron mobility of the second charge transport material ranges from approximately 1.0×10⁻⁵ cm²/Vs to 1.0×10⁻³ cm²/Vs.

In the organic electroluminescence device according to the second embodiment, when a certain level of voltage is applied between the anode 22 and the cathode 28, electrons are supplied from the cathode 28 to the organic luminescent layer 27, and holes are supplied from the anode 22 to the organic luminescent layer 27. Since the second organic luminescent material has large hole mobility but low electron mobility, holes can be supplied easily to the first and second organic luminescent layers 24 and 26. However, electrons are less likely to be supplied to the first organic luminescent layer 24 for the following reason. Among the electrons moved to the second organic luminescent layer 26, those redundant electrons, i.e., the electrons that are not recombined with the holes, can be transported to the first organic luminescent layer 24. However, the redundant electrons have low mobility within the second organic luminescent layer 26, thereby taking a lot of time to reach the first organic luminescent layer 24. For this reason, when the first and second organic luminescent layers 24 and 26 are stacked consecutively, it is difficult to obtain a charge balance between the electrons and the holes within the first organic luminescent layer 24. This difficulty in obtaining charge balance is also applied to the case where the first and second organic luminescent layers 24 and 26 are formed in a bulk type single layer. Hence, the charge separation layer 25 is interposed between the first organic luminescent layer 24 and the second organic luminescent layer 26, so that the mobility of the redundant electrons can be improved within the organic luminescent layer 27. In more detail, the charge separation layer 25 is formed of a material having greater electron mobility than the second organic luminescent material for forming the first and second organic luminescent layers 24 and 26 as a counterpart to the second organic luminescent material. As a result, transport efficiency of the redundant electrons can be improved more when the charge separation layer 25 is interposed between the first organic luminescent layer 24 and the second organic luminescent layer 26 than when the first and second organic luminescent layers 24 and 26 are stacked consecutively. Also, electron and hole concentrations for the recombination within the first organic luminescent layer 24 can be balanced. Thus, a stable light emission phenomenon caused by the electron-hole recombination can take place.

In the first and second embodiments, the charge separation layer 25 has a thickness ranging from approximately 10 nm to 100 nm. If the thickness of the charge separation layer 25 is less than approximately 10 nm, charge transport efficiency may be reduced. On the contrary, if the thickness of the charge separation layer 25 is greater than approximately 100 nm, an operation voltage of the organic electroluminescence device may increase.

The first and second organic luminescent layers 24 and 26 may be formed in a single layer or in multiple layers, and thus, are able to emit light selected from the group consisting of red light, green light and blue light. If one of the first and second luminescent layers 24 and 26 is formed in multiple layers, the charge separation layer 25 can be interposed individually therebetween.

Although not illustrated, in addition to the organic luminescent layer 27, the organic electroluminescence device according to embodiments of the present invention may further include one selected from the group consisting of a hole injection layer, a hole transport layer, a hole suppression layer, an electron transport layer, and an electron injection layer. The thicknesses and materials for the hole injection layer, the hole transport layer, the hole suppression layer, the electron transport layer, and the electron injection layer are well known in the art. For instance, detailed description thereof are provided in Korean patent No. 0424090 issued to J. Y. Lee, entitled “Hole Transport Layer for Electroluminescence Device, Electroluminescence Device Using the Same, and Method thereof,” Korean Laid-Open No. 2004-0081528, entitled “Organic Electroluminescence Display Device,” and Korean Laid-Open No. 2004-0070561, entitled “Organic Electroluminescence Device”, and the entire contents thereof are incorporated herein by reference.

Although materials for the hole transport layer are not limited, the hole transport layer may include one or more selected from carbazoles and arylamines. In more detail, the hole transport layer may include at least one selected from the group consisting of 1,3,5-tricarbazolylbenzene, 4,4′-biscarbazolylbipheyl, polyvinylcarbazole, m-biscarbazolylphenyl, 4,4′-biscarbazolyl-2,2′-dimethylbiphenyl, 4,4′4″-tri(N-carbazolyl)triphenylamine, 1,3,5-tri(2-carbazolylphenyl)benzene, 1,3,5-tris(2-carbazolyl-5-methoxyphenyl)benzene, bis(4-carbazolylphenyl )silane, TPD (N,N′-bis(3-methylphenyl)-N,N′-diphenyl-[1,1-biphenyl]-4,4′diamine), α-NPD (N,N′-di(naphthalene-1-yl)-N,N′-diphenyl benzidine), NPB (N,N′-dipheyl-N,N′-bis(1-naphthyl)-(1,1′-biphenyl)-4,4′-diamine), IDE320 marketed by Idemitsu Co., TFB (poly(9,9-dioctylfluorene-co-N-(4-butylphenyl)diphenylamine)), PFB (poly(9,9-dioctylfluorene-co-bis-N,N′-(4-butylphenyl)-bis-N,N′-phenyl-1,4-phenylenedi amine)) and a combination thereof. However, the hole transport layer is not limited to these listed materials.

### EXAMPLE 1

According to the first embodiment, an organic electroluminescence device was configured to have a stack structure of ITO/PEDOT/Red polymer/CSL/Blue polymer/BaF₂/Ca/Al. The ITO, PEDOT, Red polymer, CSL, Blue polymer, BaF₂, Ca, and Al had respective thicknesses of approximately 150 nm, 50 nm, 40 nm, 20 nm, 40 nm, 5 nm, 3 nm, and 200 nm. Each of these component layers of the stack structure could be formed using the known methods in the art. For instance, a method selected from the group consisting of a spin coating method, a dip coating method, a spray coating method, a roll coating method, and a combination thereof might be used to form the component layers. However, the component layers can be formed using other or modified methods.

The CSL served as a charge separation layer and was formed of TFB. The Red polymer layer was obtained using RP119 marketed by Dow-Sumitomo Co. The Blue polymer layer was formed of poly(2′,3′,6′,7′-tetraoctyloxy spirofluorene)-co-penoxazine, and detailed description of the Blue polymer layer is revealed in Korean Laid-Open No. 2003-0097658, entitled “Blue Electroluminescent Polymer and Organic-Electroluminescent Device Manufactured by Using the Same.

### COMPARATIVE EXAMPLE 1

An organic electroluminescence device was manufactured in the same manner as in Example 1, except that the CSL was not formed between Red polymer and Blue polymer.

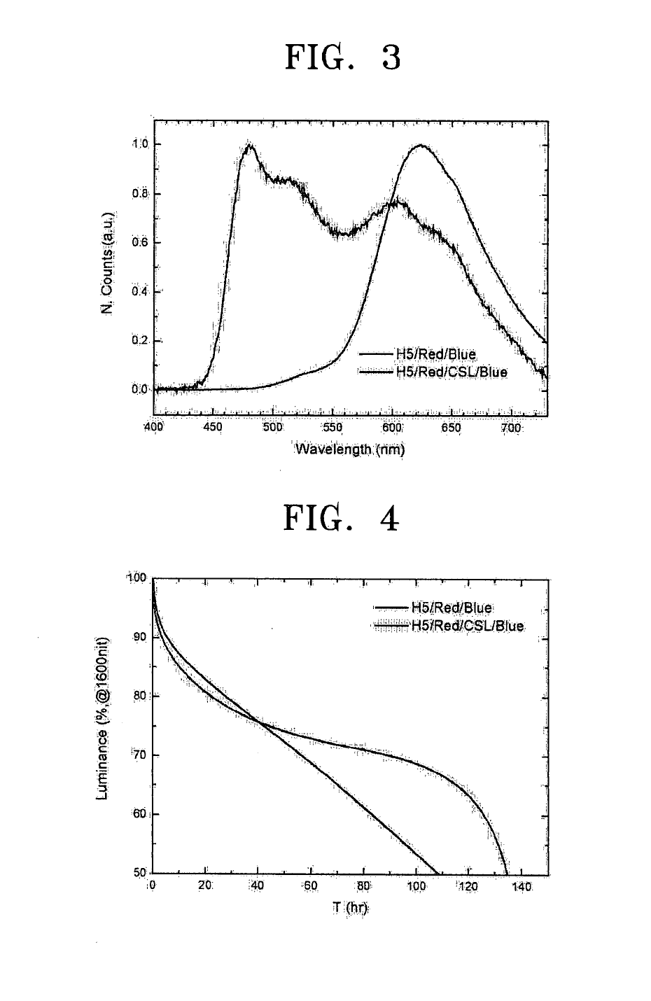

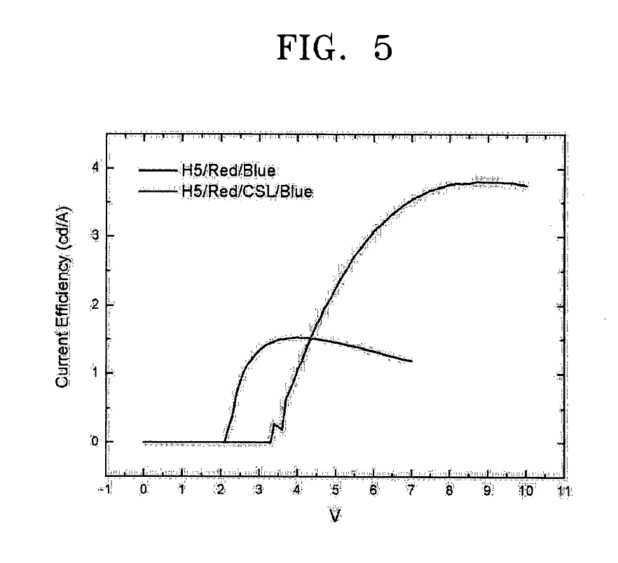

FIG. 3 is a graph illustrating optical wavelength characteristics of the organic electroluminescence devices fabricated according to Example 1 and Comparative Example 1. FIG. 4 is a graph illustrating luminance characteristics of the organic electroluminescence devices fabricated according to Example 1 and Comparative Example 1. The reference letters ‘nit’ in FIG. 4 denotes cd/m². FIG. 5 is a graph illustrating current efficiency of the organic electroluminescence devices fabricated according to Example 1 and Comparative Example 1.

### EXAMPLE 2

According to the second embodiment, another organic electroluminescence device was configured to have a stack structure of ITO/HIL/HTL/Red polymer/CSL/Blue polymer/Alq/LiF/Al. The ITO, HIL, HTL, Red polymer, CSL, Blue polymer, Alq, LiF, and Al had respective thicknesses of approximately 150 nm, 30 nm, 20 nm, 20 nm, 10 nm, 20 nm, 20 nm, 0.5 nm, and 200 nm. The CSL served as a charge separation layer. The Red polymer layer and the Blue polymer layer were formed of a fluorescent material including triphenyl amine.

### COMPARATIVE EXAMPLE 2

An organic electroluminescence device was manufactured in the same manner as in Example 2, except that the CSL was not formed between Red polymer and Blue polymer.

Table 1 below summarizes CIE chromaticity, luminescent efficiency, and lifetime of the organic electroluminescence devices fabricated according to Examples 1 and 2 and Comparative Examples 1 and 2.

TABLE 1

| | CIE | Efficiency | Lifetime |
|---|---|---|---|
| Comparative Example 1 | (0.66, 0.33) | 1.5 cd/A | 108 hrs |
| Example 1 | (0.31, 0.36) | 3.8 cd/A | 134 hrs @ 1600 nit |
| Comparative Example 2 | (0.15, 0.18) | 4.4 cd/A | 450 hrs |
| Example 2 | (0.32, 0.35) | 6.8 cd/A | 590 hrs @ 2000 nit |

According to the embodiments of the present invention, interposing the charge separation layer between the multiple layers of the organic luminescent layer (i.e., the first and second organic luminescent layers) allows formation of at least two layers of electron-hole recombination zones separated within the organic luminescent layer. Particularly, since each of the first and second organic luminescent layers can provide the electron-hole recombination zone, this electron-hole recombination zone structure can improve luminescent efficiency of the organic electroluminescence device.

Also, the interposed charge separation layer is formed of a material having large electron or hole mobility, and thus, electrons or holes in the first and second organic layers can be more stably supplied with a better concentration balance as compared with the conventional organic electroluminescence device. As a result, electron and hole concentrations for the electron-hole recombination within the first and second organic luminescent layers can be balanced and thereby allow stable light emission. Accordingly, when compared with the conventional organic luminescent layer, the luminescent efficiency of the organic luminescent layer can be improved to a greater extent, and the lifetime of the organic electroluminescence devices can be lengthened.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An organic electroluminescence device, comprising:
an anode;
an organic luminescent layer formed on the anode and comprising:
a first organic luminescent layer;
a second organic luminescent layer; and
a charge separation layer interposed between the first organic luminescent layer and the second organic luminescent layer, the charge separation layer comprising one of a first charge transport material having greater hole mobility than materials for forming the first and second luminescent layers and a second charge transport material having greater electron mobility than materials for forming the first and second luminescent layers; and
a cathode formed on the organic luminescent layer.

2. The organic electroluminescence device of claim 1, wherein the first charge transport material has hole mobility ranging from approximately 1.0×10⁻⁵ cm²/Vs to 1.0×10⁻³ cm²/Vs.

3. The organic electroluminescence device of claim 2, wherein the first charge transport material comprises one selected from the group consisting of TFB (poly(9,9-dioctylfluorene-co-N-(4-butylphenyl)diphenylamine)), BFE (poly(9,9′-dioctylfluorene-co-bis-N,N′-(4-butylphenyl)-bis-N,N′-phenylbenzidine), and PFB (poly(9,9-dioctylfluorene-co-bis-N,N′-(4-butylphenyl)-bis-N,N′-phenyl-1,4-phenylenedi amine).

4. The organic electroluminescence device of claim 1, wherein the second charge transport material has electron mobility ranging from approximately 1.0×10⁻⁵ cm²/Vs to 1.0×10⁻³ cm²/Vs.

5. The organic electroluminescence device of claim 4, wherein the second charge transport material comprises one selected from the group consisting of PBD (1,3,4-oxadiazole derivatives), Alq3 (tris(8-quinolinolato)aluminum complex) and TPBi (N,arylbenzimidazoles).

6. The organic electroluminescence device of claim 1, wherein the charge separation layer has a thickness ranging from approximately 10 nm to 100 nm.

7. The organic electroluminescence device of claim 1, wherein the first and second organic luminescent layers comprise a first organic luminescent material having greater electron mobility than hole mobility, and the charge separation layer comprises the first charge transport material.

8. The organic electroluminescence device of claim 7, wherein the first organic luminescent material comprises one selected from the group consisting of PF (polyfluorene) based polymers, derivatives of PF based polymers, PSF (polyspirofluorene) based polymers, and derivatives of PSF based polymers.

9. The organic electroluminescence device of claim 7, wherein the first charge transport material has hole mobility ranging from approximately 1.0×10⁻⁵ cm²/Vs to 1.0×10⁻³ cm²/Vs.

10. The organic electroluminescence device of claim 9, wherein the first charge transport material comprises one selected from the group consisting of TFB (poly(9,9-dioctylfluorene-co-N-(4-butylphenyl)diphenylamine)), BFE (poly(9,9′-dioctylfluorene-co-bis-N,N′-(4-butylphenyl)-bis-N,N′-phenylbenzidine), and PFB (poly(9,9-dioctylfluorene-co-bis-N,N′-(4-butylphenyl)-bis-N,N′-phenyl-1,4-phenylenedi amine).

11. The organic electroluminescence device of claim 1, wherein the first and second organic luminescent layers comprises a second organic luminescent material having greater hole mobility than electron mobility, and the charge separation layer comprises the second charge transport material.

12. The organic electroluminescence device of claim 11, wherein the second organic luminescent material comprises triphenyl amine.

13. The organic electroluminescence device of claim 11, wherein the second charge transport material has electron mobility ranging from approximately 1.0×10⁻⁵ cm²/Vs to 1.0×10⁻³ cm²/Vs.

14. The organic electroluminescence device of claim 13, wherein the second charge transport material comprises one selected from the group consisting of PBD (1,3,4-oxadiazole derivatives), Alq3 (tris(8-quinolinolato)aluminum complex) and TPBi (N,arylbenzimidazoles).

15. The organic electroluminescence device of claim 1, wherein each of the first and second organic luminescent layers emits light comprising one selected from the group consisting of red light, green light and blue light.

16. The organic electroluminescence device of claim 15, wherein each of the first and second organic luminescent layers are formed in one of a single layer and multiple layers.

17. The organic electroluminescence device of claim 16, wherein when the first and second organic luminescent layers are formed in multiple layers, the charge separation layer is interposed individually between the multiple layers.

18. An organic electroluminescence device, comprising:
an anode;
a cathode; and
an organic luminescent layer formed between the anode and the cathode, the organic luminescent layer comprising:
a first organic luminescent layer formed of a first organic luminescent material;
a second organic luminescent layer formed of a second organic luminescent material, the first organic luminescent material and the second organic luminescent material having an electron mobility greater than a hole mobility or a hole mobility greater than an electron mobility; and
a charge separation layer interposed between the first organic luminescent layer and the second organic luminescent layer, the charge separation layer formed of one of (1) a first charge transport material having greater hole mobility than the first organic luminescent material and the second organic luminescent material when electron mobility of the first organic luminescent material and the second organic luminescent material is greater than hole mobility of the first organic luminescent material and the second organic luminescent material and (2) a second charge transport material having greater electron mobility than the first organic luminescent material and the second organic luminescent material when electron mobility of the first organic luminescent material and the second organic luminescent material is greater than hole mobility of the first organic luminescent material and the second organic luminescent material.

19. The organic electroluminescence device of claim 18, wherein the charge separation layer is formed of the first charge transport material.

20. The organic electroluminescence device of claim 19, wherein the first charge transport material comprises one selected from the group consisting of poly(9,9-dioctylfluorene-co-N-(4-butylphenyl)diphenylamine), poly(9,9′-dioctylfluorene-co-bis-N,N′-(4-butylphenyl)-bis-N,N′-phenylbenzidine, and poly(9,9-dioctylfluorene-co-bis-N,N′-(4-butylphenyl)-bis-N,N′-phenyl-1,4-phenylenedi amine.

21. The organic electroluminescence device of claim 18, wherein the charge separation layer is formed of the second charge transport material.

22. The organic electroluminescence device of claim 21, wherein the second charge transport material comprises one selected from the group consisting of PBD (1,3,4-oxadiazole derivatives), Alq3 (tris(8-quinolinolato)aluminum complex) and TPBi (N,arylbenzimidazoles).

23. The organic electroluminescence device of claim 18, wherein the first organic luminescent material and the second organic luminescent material are the same.

24. The organic electroluminescence device of claim 1, wherein each of the first and second organic luminescent layers are formed in a single layer.

25. An organic electroluminescence device, comprising:
an anode;
a cathode; and
an organic luminescent layer formed between the anode and the cathode, the organic luminescent layer comprising:
a first electron-hole recombination zone;
a second electron-hole recombination zone, the first organic electron-hole recombination zone and the second electron-hole recombination zone having one property of electron mobility greater than hole mobility and hole mobility greater than an electron mobility; and
a charge separation layer interposed between the first electron-hole recombination zone and the second electron-hole recombination zone, the charge separation layer formed of one of a first charge transport material and a second charge transport material, the first charge transport material comprising one selected from the group consisting of poly(9,9-dioctylfluorene-co-N-(4-butylphenyl)diphenylamine), poly(9,9′-dioctylfluorene-co-bis-N,N′-(4-butylphenyl)-bis-N,N′-phenylbenzidine, and poly(9,9-dioctylfluorene-co-bis-N,N′-(4-butylphenyl)-bis-N,N′-phenyl-1,4-pheny lenediamine, the second charge transport material comprising one selected from the group consisting of PBD (1,3,4-oxadiazole derivatives), Alq3 (tris(8-quinolinolato)aluminum complex) and TPBi (N,arylbenzimidazoles).
